(19) United States
(12) Patent Application Publication
(10) Pub. No.: US 2011/0198115 A1
(43) Pub. Date: Aug. 18, 2011

(54) ELECTRONIC COMPONENT BUILT-IN MODULE AND METHOD OF MANUFACTURING THE SAME

(75) Inventors: Yukihiro AZUMA, Tokyo (JP); Seiichi TAJIMA, Tokyo (JP); Shigeru ASAMI, Tokyo (JP); Hiroki HARA, Tokyo (JP); Shuichi TAKIZAWA, Tokyo (JP); Kenichi KAWABATA, Tokyo (JP)

(73) Assignee: TDK CORPORATION, Tokyo (JP)

(21) Appl. No.: 13/025,658

(22) Filed: Feb. 11, 2011

(30) Foreign Application Priority Data
Feb. 17, 2010 (JP) 2010-032521

(51) Int. Cl. H05K 1/16; H05K 3/34

(52) U.S. Cl. 174/260; 29/840

(57) ABSTRACT

An electronic component built-in module includes an electronic component, a substrate on which the electronic component is mounted, a first resin covering the electronic component and the substrate, and a second resin covering the surface of the first resin. The first resin is formed of a resin including pores. The first resin is formed so that the thickness of the first resin on an area where the electronic component is not mounted is larger than that on an area where the electronic component is mounted on the surface of the substrate. A porosity of the second resin is smaller than that of the first resin.

### CROSS-REFERENCE TO RELATED APPLICATIONS

This application is based upon and claims the benefit of priority from Japanese Patent Application No. 2010-032521, filed on Feb. 17, 2010, the entire contents of which are incorporated herein by reference.

### BACKGROUND OF THE INVENTION

1. Field of the Invention

The present invention relates to an electronic component built-in module in which electronic components are covered with an insulating resin and a method of manufacturing the same.

2. Description of the Related Art

An electronic component built-in module is an electronic component in which a plurality of electronic components such as passive elements and active elements are mounted on a substrate by solder or the like to have a set of functions. When such an electronic component built-in module is mounted on a mounting substrate of an electronic device, terminal electrodes of the electronic component built-in module and terminal electrodes of the mounting substrate are bonded by solder. At this time, it is possible that solder which bonds the electronic components in the electronic component built-in module to the substrate melts and the solder moves or spreads. Japanese Laid-open Patent Publication No. 2007-234930 discloses a method in which a linear expansion coefficient of a sealing resin of the electronic component built-in module is regulated to be within a predetermined range.

### SUMMARY OF THE INVENTION

An electronic component built-in module according to an aspect of the present invention includes an electronic component; a substrate on which the electronic component is mounted; a first resin that is formed of a resin including pores and covers the electronic component and the substrate and whose thickness on an area where the electronic component is not mounted on a surface of the substrate is larger than that on a surface of the electronic component opposite to a surface facing the substrate; and a second resin that covers a surface of the first resin and has a porosity smaller than that of the first resin.

A method of manufacturing an electronic component built-in module according to another aspect of the present invention includes mounting an electronic component on a substrate by solder; coating a first resin solution into which fillers are mixed on the electronic component mounted on the substrate and the substrate; reducing at least a thickness of the first resin solution coated on a surface of the electronic component opposite to a surface attached to the substrate; curing the first resin; covering the cured first resin with a second resin; and curing the second resin.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a cross-sectional view of an electronic component built-in module according to an embodiment of the present invention;

FIG. 2 is a side view showing a state in which the electronic component built-in module according to the embodiment is mounted on a substrate;

FIG. 3 is a schematic diagram showing a structure of a first resin included in the electronic component built-in module according to the embodiment;

FIG. 4 is an enlarged view showing a structure in which the first resin covers electronic components in the electronic component built-in module according to the embodiment;

FIG. 5 is an enlarged view showing a structure in which the first resin covers electronic components in the electronic component built-in module according to the embodiment;

FIG. 6 is a flowchart showing a method for manufacturing the electronic component built-in module according to the embodiment;

FIG. 7A is an illustration of the method for manufacturing the electronic component built-in module according to the embodiment;

FIG. 7B is an illustration of the method for manufacturing the electronic component built-in module according to the embodiment;

FIG. 7C is an illustration of the method for manufacturing the electronic component built-in module according to the embodiment;

FIG. 7D is an illustration of the method for manufacturing the electronic component built-in module according to the embodiment;

FIG. 7E is an illustration of the method for manufacturing the electronic component built-in module according to the embodiment;

FIG. 7F is an illustration of the method for manufacturing the electronic component built-in module according to the embodiment;

FIG. 8A is a diagram showing an example of a method for forming the first resin;

FIG. 8B is a diagram showing an example of a method for forming the first resin;

FIG. 9A is an illustration showing a manufacturing method when the first resin is not formed on the surfaces of the electronic components in the method for manufacturing the electronic component built-in module according to the embodiment;

FIG. 9B is an illustration showing the manufacturing method when the first resin is not formed on the surfaces of the electronic components in the method for manufacturing the electronic component built-in module according to the embodiment; and

FIG. 9C is an illustration showing the manufacturing method when the first resin is not formed on the surfaces of the electronic components in the method for manufacturing the electronic component built-in module according to the embodiment.

### DETAILED DESCRIPTION OF THE PREFERRED EMBODIMENTS

Hereinafter, an embodiment for implementing the present invention (an embodiment of the present invention) will be described with reference to the drawings. The embodiment described below does not limit the present invention. Constituent elements disclosed in the embodiment described below include those that can be easily assumed by those skilled in the art or that are substantially equivalent or within an equivalent range. Further, the constituent elements disclosed in the embodiment described below can be arbitrarily combined.

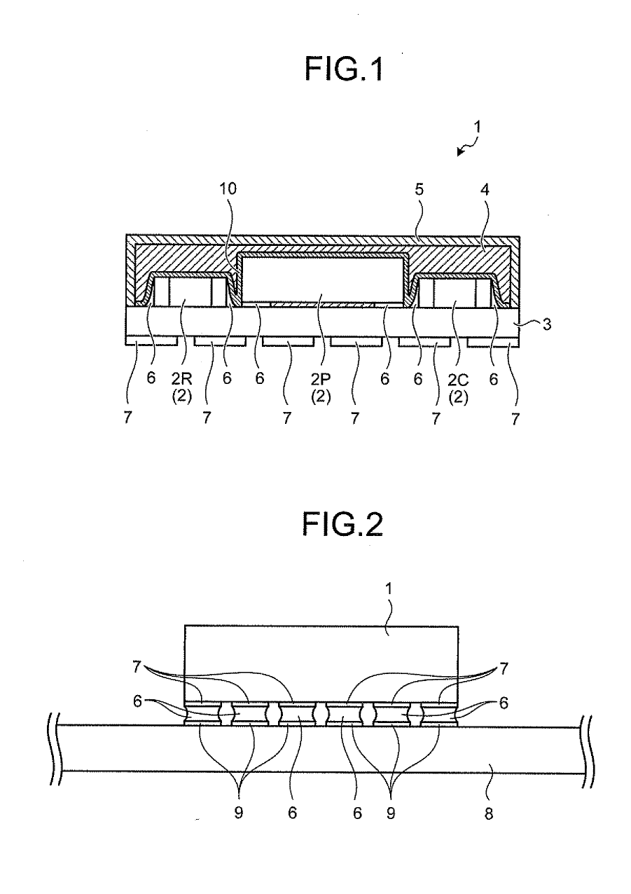

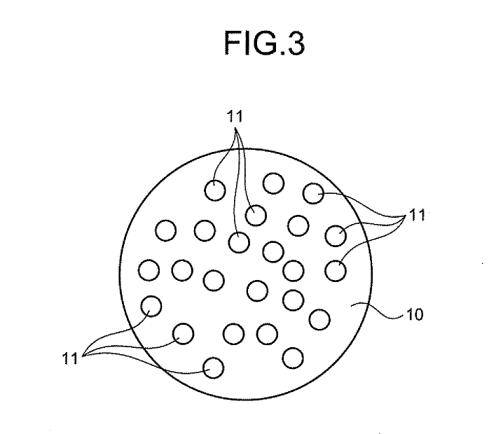

FIG. 1 is a cross-sectional view of an electronic component built-in module according to the embodiment. FIG. 2 is a side view showing a state in which the electronic component built-in module according to the embodiment is mounted on a substrate. FIG. 3 is a schematic diagram showing a structure of a first resin included in the electronic component built-in module according to the embodiment. As shown in FIG. 1, an electronic component built-in module 1 is an electronic component in which a plurality of electronic components 2 are mounted on a substrate (a module substrate) 3 to have a set of functions.

The electronic components 2 included in the electronic component built-in module 1 include, for example, passive elements such as a coil, a capacitor, and a resistor, however active elements such as a diode and a transistor, an Integral Circuit (IC), and the like may be mounted on the surface of the module substrate 3 or inside the module substrate 3 as the electronic components 2. The electronic components 2 are not limited to those. In the embodiment, a capacitor 2C, an IC 2P, and a resistor 2R are mounted on the module substrate 3, and the capacitor 2C, the IC 2P, and the resistor 2R are arbitrarily referred to as the electronic component 2 if necessary.

As shown in FIG. 1, the electronic component built-in module 1 includes the module substrate 3 on which the electronic components 2 are mounted, a first resin 10 covering the electronic components 2 and the module substrate 3, a second resin 4 covering the surface of the first resin 10, and a shield layer 5 covering the second resin 4. Terminal electrodes of the electronic components 2 and terminal electrodes of the module substrate 3 are bonded by solder 6. In this way, the electronic components 2 are mounted on the module substrate 3. At least an electrically insulating material (insulating resin) is used as the first resin 10. The second resin 4 is also desired to be an electrically insulating material. In the embodiment, insulating resins having electrically insulating properties are used as the first and the second resins.

As shown in FIG. 1, in the electronic component built-in module 1, the first resin 10 covers the electronic components 2 mounted on the module substrate 3 and the surface (component-mounting surface) of the module substrate 3 on which the electronic components 2 are mounted. The first resin 10 is covered by the second resin 4. In this way, in the electronic component built-in module 1, the second resin 4 covers a plurality of electronic components 2 and the component-mounting surface via the first resin 10, so that the module substrate 3 and a plurality of electronic components 2 are integrated together and the strength is secured. In the electronic component built-in module 1, the first resin 10 covers a plurality of electronic components 2 and the component-mounting surface, so that the solder is prevented from moving or spreading in a reflow process in which the electronic component built-in module 1 is mounted.

The shield layer 5 is formed on the surface of the second resin 4 that covers a plurality of electronic components 2. In the embodiment, the shield layer 5 is formed by a conductive material (material having an electrical conductivity: metal is used in the embodiment). In the embodiment, the shield layer 5 may be formed by a single conductive material or a plurality of layers of conductive materials. The shield layer 5 covers the surface of the second resin 4, and thereby shields the electronic components 2 encapsulated in the second resin 4 from high-frequency noises and electromagnetic waves coming from outside of the electronic component built-in module 1, and blocks high-frequency noises emitted from the electronic components 2. In this way, the shield layer 5 functions as an electromagnetic shield. In the embodiment, the shield layer 5 covers the entire surface of the second resin 4. However, the shield layer 5 only needs to cover the second resin 4 to exert a function as an electromagnetic shield, and does not necessarily need to cover the entire surface of the second resin 4. Therefore, the shield layer 5 only needs to cover at least a part of the surface of the second resin 4. When the shield layer 5 is not necessary, the shield layer 5 need not be formed.

The module substrate 3 includes terminal electrodes (module terminal electrodes) 7 on a surface opposite to the component-mounting surface. The module terminal electrodes 7 are electrically connected to the electronic components 2 included in the electronic component built-in module 1 and, as shown in FIG. 2, bonded by solder 6 to terminal electrodes (mounting substrate terminal electrodes) 9 of the substrate (that is a substrate included in an electronic device, and hereinafter referred to as mounting substrate) 8 to which the electronic component built-in module 1 is attached. By doing this, the electronic component built-in module 1 is attached to the mounting substrate 8, and electrical signals and electric powers are transmitted and received between the electronic components 2 and the mounting substrate 8.

The mounting substrate 8 shown in FIG. 2 is a substrate on which the electronic component built-in module 1 is mounted, and for example, mounted in an electronic device (vehicle-mounted electronic device, portable electronic device, and the like). When mounting the electronic component built-in module 1 on the mounting substrate 8, for example, a solder paste including the solder 6 is printed on the mounting substrate terminal electrodes 9, and the electronic component built-in module 1 is mounted on the mounting substrate 8 by using a mounting apparatus (mounter). Then, the mounting substrate 8 on which the electronic component built-in module 1 is mounted is put into a reflow furnace and the solder paste is heated, and thereby the solder 6 in the solder paste is melted. The solder 6 melts and thereafter hardens, and thereby the module terminal electrodes 7 and the mounting substrate terminal electrodes 9 are bonded together. Thereafter, fluxes attached to the surfaces of the electronic component built-in module 1 and the mounting substrate 8 are washed off, and the electronic component built-in module 1 is mounted on the mounting substrate 8.

In the electronic component built-in module 1, the electronic components 2 are covered and sealed by the second resin 4, and thus, the solder 6 that bonds the electronic components 2 to the module substrate 3 is also covered and sealed by the second resin 4. As a result, the solder 6 that is sealed by the second resin 4 is melted again by the reflow in a secondary mounting operation (the reflow to mount the electronic component built-in module 1 on the mounting substrate 8). At this time, by forces caused by water vapor generated from moisture contained in the second resin 4 and gas generated from the re-melted solder 6 or residual flux, the solder 6 sealed by the second resin 4 moves or spreads in a gap between the component-mounting surface of the module substrate 3 and the second resin 4. The solder 6 expands when the solder 6 is melted by the reflow in the secondary mounting operation, so that the solder 6 may move rapidly.

In the embodiment, the first resin 10 that includes pores 11 as shown in FIG. 3 is disposed between the second resin 4 and the electronic components 2 and between the second resin 4 and the module substrate 3 in the electronic component built-in module 1, and the first resin 10 also covers the electronic components 2 and the solder 6 that bonds the electronic components 2. In the electronic component built-in module 1, the first resin 10 including the pores 11 covers the electronic components 2 and the solder 6 that bonds the electronic components 2, so that, in the reflow process of the secondary mounting operation, the pores 11 expand by a heat of the reflow in the secondary mounting operation. The expanding pores 11 can absorb the water vapor generated from the moisture contained in the second resin 4 and the gas generated from the solder 6, so that an effect to prevent the solder 6 from moving or spreading can be obtained.

In particular, when the electronic component built-in module 1 is sealed by the shield layer 5, the water vapor, residues of the evaporated flux, and the gas generated from the solder 6 are enclosed in the electronic component built-in module 1, and an environment is created in which the solder 6 easily moves or spreads. However, the pores 11 of the first resin 10 included in the electronic component built-in module 1 effectively absorb the water vapor and the gas generated in the electronic component built-in module 1, so that it is possible to effectively prevent the solder 6 from moving or spreading. As described above, the embodiment is preferable, in particular when the electronic component built-in module 1 includes the shield layer 5.

The second resin 4 that covers the first resin 10 has a porosity smaller than that of the first resin 10. The porosity is a ratio (vol %) of the volume of the pores 11 per unit volume. By decreasing the porosity of the second resin 4 to a value smaller than that of the first resin 10, the second resin 4 becomes stronger than the first resin 10. Such a second resin 4 seals the electronic components 2 and the first resin 10 on the module substrate 3 to secure a sufficient strength of the electronic component built-in module 1. The porosity of the second resin 4 may be 0%.

The pores 11 included in the first resin 10 is formed by, for example, adding fillers to a resin that is a base material of the first resin 10 and curing the resin to dispose the resin into gaps between the fillers. When the porosity is smaller than or equal to 0.1 vol %, it is impossible to obtain a mitigation effect against thermal shock caused by a rapid movement of the melted solder 6 or rapid gas expansion. Thus, the solder 6 moves in the reflow process of the secondary mounting operation, so that there is a risk to cause a short circuit or a contact failure of the electronic components 2.

When the porosity is greater than or equal to 30 vol %, there is a risk that the strength of the first resin 10 decreases and cracks are easily generated. And at the same time, the pores 11 are easily connected to each other, so that the pores 11 are formed into a pipe shape. Therefore, in the reflow process of the secondary mounting operation, there is a risk that the solder 6 is melted along the pores 11 having a pipe shape. On the other hand, it is preferable to set the porosity to be smaller than or equal to 10 vol % because, when the porosity is smaller than or equal to 10 vol %, the number of connections between the pores 11 decreases and the melted solder 6 is highly prevented from moving. As described above, to effectively prevent the solder 6 from moving or spreading, it is preferable to set the porosity of the first resin 10 to be greater than or equal to 0.1 vol % and smaller than or equal to 30 vol %, and more preferable to set the porosity to be greater than or equal to 0.1 vol % and smaller than or equal to 10 vol %.

When the average diameter (D50) of the pores 11 shown in FIG. 3 is smaller than 0.1 μm, it is impossible to obtain a sufficient effect to prevent the melted solder 6 from moving and there is a risk to cause a short circuit or a contact failure of the electronic components 2. When the average diameter (D50) of the pores 11 is greater than or equal to 3 μm, the solder 6 melted into a large pore among the pores 11 may move, however, if the diameter of the pore is smaller than or equal to 10 μm, there is no problem with a short circuit or electrical characteristics of the electronic components 2 included in the electronic component built-in module 1. When the average diameter (D50) of the pores 11 is within a range between 0.1 μm and 10 μm, it is possible to sufficiently prevent the melted solder 6 from moving. Therefore, from a view point to effectively prevent the solder 6 from moving or spreading, it is preferable that the average diameter (D50) of the pores 11 is greater than or equal to 0.1 μm and smaller than or equal to 10 μm, and more preferable that the average diameter (D50) is greater than or equal to 0.1 μm and smaller than or equal to 3 μm. Regarding the distribution of the pores 11, it is preferable that D50/(D90−D10) is greater than or equal to 0.1 and smaller than or equal to 0.8. Based on this, the distribution of the fillers and the distribution of the pores 11 in the first resin 10 are improved. The average diameter (D50) is a diameter of the integrated value 50% (median diameter) when the diameters of a plurality of pores 11 are measured, D90 is a diameter when the integrated value is 90%, and D10 is a diameter when the integrated value is 10%.

The average diameter of the pores 11 was measured from images obtained by cutting off a completed electronic component built-in module 1 at an appropriate position, making a cut surface without resin dropping by ion milling the cut surface, and taking photographs of any three positions in the cut surface by using a scanning electron microscope (SEM). In the embodiment, the magnification was 3000 times. The distribution of the pores 11 was defined from D50 obtained from the images, D10 corresponding to a cumulative frequency diameter of 10%, and D90 corresponding to a cumulative frequency diameter of 90%. The porosity was measured from an image obtained by cutting off a completed electronic component built-in module 1 at an appropriate position, making a cut surface without resin dropping by ion milling the cut surface, and taking a photograph of the cut surface by using a SEM (magnification was 3000 times). The obtained image was binarized so that only the pores are blackened, and the porosity was calculated as a volume ratio of the pores. In the embodiment, the ratio of the area of the pores to the entire area of the obtained image is assumed to be the volume ratio of the pores.

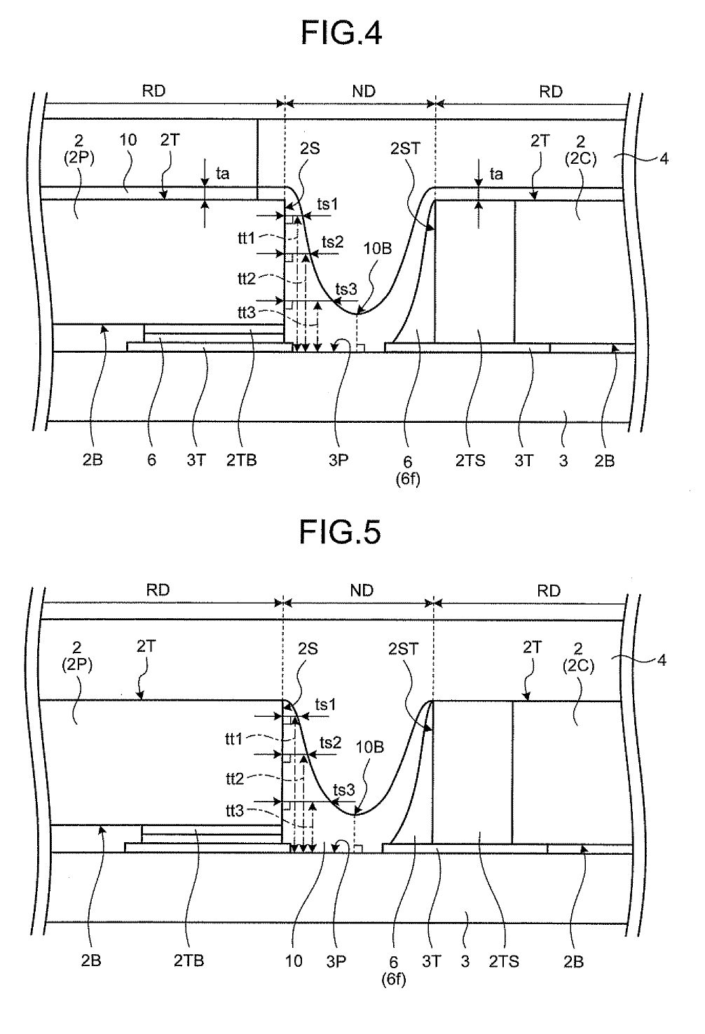

FIGS. 4 and 5 are enlarged views showing a structure in which the first resin covers the electronic components in the electronic component built-in module according to the embodiment. In the electronic component built-in module 1, the first resin 10 covers the electronic components 2 and the module substrate 3. As shown in FIG. 4, the first resin 10 has a structure in which the thicknesses (ts1, ts2, ts3, tt1, tt2, and tt3) on the area ND where nothing is mounted are larger than the thickness (ta) on the surface RD of the electronic component opposite to the substrate. The surface RD of the electronic component opposite to the substrate is the surface opposite to the surface of the electronic component 2 facing the module substrate 3 (more specifically, the surface 3P of the module substrate 3 (substrate surface)). The area ND where nothing is mounted is an area where the electronic component 2 is not mounted. The first resin 10 need not be present between the substrate surface 3P and the electronic component 2.

The first resin 10 on the surface RD of the electronic component opposite to the substrate is present on the surface 2T (top surface) opposite to the surface 2B (the surface through which the electronic component 2 is attached to the module substrate 3; bottom surface) of the electronic component 2 facing the substrate surface 3P. By making the thickness of the first resin 10 on the surface RD of the electronic component opposite to the substrate smaller than the thickness of the first resin 10 on the area ND where nothing is mounted, heat generated from the electronic component 2 is released easily. In particular, when the electronic component 2 is an active element (for example, IC 22), it is advantageous because the amount of discharged heat is large.

As shown in FIG. 5, the thickness ta of the first resin 10 on the surface RD of the electronic component opposite to the substrate may be 0. Based on this, heat dissipation from the electronic component 2 can be further facilitated. By making the thickness of the first resin 10 on the surface RD of the electronic component opposite to the substrate smaller than the thickness of the first resin 10 on the area ND where nothing is mounted, the height of the electronic component built-in module 1 can be low, so that making the thickness of the first resin 10 smaller is preferable to lower the height of the component.

By making the thicknesses (ts1, ts2, ts3, tt1, tt2, and tt3) of the first resin 10 on the area ND where nothing is mounted larger than the thickness of the first resin 10 on the surface RD of the electronic component opposite to the substrate, the solder 6 that bonds the electronic components 2 to the terminal electrodes (substrate terminal electrodes) 3T of the module substrate 3 can be reliably covered by the first resin 10. Based on this, when the solder 6 is heated by the reflow in the secondary mounting operation, the pores 11 (see FIG. 3) in the first resin 10 on the area ND where nothing is mounted can effectively absorb gas generated from the solder 6, and also can absorb thermal shock caused by the melting and expansion of the solder 6, so that it is possible to more reliably prevent the solder 6 from moving or spreading.

For example, the IC 2P includes terminal electrodes (component terminal electrodes) 2TB on the bottom surface 2B, and the component terminal electrodes 2TB and the substrate terminal electrodes 3T are bonded together by the solder 6. By forming the first resin 10 into the structure described above, the solder 6 is reliably covered by the first resin 10 present on the area ND where nothing is mounted. Based on this, the first resin 10 on the area ND where nothing is mounted effectively absorbs the gas generated from the solder 6 and the thermal shock caused by the solder 6 in the reflow process of the secondary mounting operation, so that the first resin 10 can more reliably prevent the solder 6 from moving or spreading.

Regarding the capacitor 2C shown in FIGS. 4 and 5, end surfaces 2ST of component terminal electrodes 2TS provided on both ends of the capacitor 2C are bonded to the substrate terminal electrodes 3T by the solder 6. In this bonding state, the solder 6 forms a fillet 6f. By forming the first resin 10 into the structure described above, the first resin 10 present on the area ND where nothing is mounted reliably covers the entire fillet 6f. Based on this, the first resin 10 effectively absorbs the gas generated from the solder 6 and the thermal shock caused by the solder 6 in the reflow process of the secondary mounting operation, so that the first resin 10 can more reliably prevent the solder 6 from moving or spreading.

As shown in FIGS. 4 and 5, the area ND where nothing is mounted is an area where the electronic component 2 is not present. When making the thickness of the first resin 10 on the area ND where nothing is mounted larger than the thickness of the first resin 10 on the surface RD of the electronic component opposite to the substrate, it is possible to make the thickness of the second resin 4 covering the first resin 10 on the area ND where nothing is mounted larger than the thickness of the second resin 4 on the surface RD of the electronic component opposite to the substrate. Based on this, the area ND where nothing is mounted has a structure in which the first resin 10 is supported by the second resin 4 having strength larger than that of the first resin 10. Thus, even when the first resin 10 receives thermal shock from the solder 6 in the reflow process of the secondary mounting operation, the second resin 4 can reliably regulate the movement of the first resin 10. As a result, the solder 6 can be more reliably prevented from moving or spreading.

In the embodiment, the thickness to of the first resin 10 on the surface RD of the electronic component opposite to the substrate and the thicknesses (ts1, ts2, ts3, tt1, tt2, and tt3) of the first resin 10 on the area ND where nothing is mounted are essentially lengths in a direction perpendicular to a surface of the electronic component 2 (top surface 2T, side surface 2S, end surface 2ST of component terminal electrode 2TS, or the like). In this case, the maximum value of the thickness of the first resin 10 on the area ND where nothing is mounted is the length from the side surface 2S of the electronic component 2 to the bottom position 10B of the U—shape of the first resin 10 (the position where the length between the surface of the first resin 10 on the area ND where nothing is mounted and the substrate surface 32 is smallest).

In the embodiment, in the first resin 10 on the area ND where nothing is mounted, the thickness from the side surface 2S of the electronic component 2 increases as the surface of the first resin 10 approaches the module substrate 3 (when the electronic component 2 has the component terminal electrode 2TS, the end surface 2ST corresponds to the side surface of the electronic component 2). For example, in the examples shown in FIGS. 4 and 5, when the electronic component 2 is the IC 22, the thicknesses from the side surface 2S, in other words, the lengths in the direction perpendicular to the side surface 2S, are indicated by ts1, ts2, and ts3, and ts1<ts2<ts3. By forming the first resin 10 as described above, a structure in which the thickness of the first resin 10 on the area ND where nothing is mounted is larger than the thickness of the first resin 10 on the surface RD of the electronic component opposite to the substrate can be reliably implemented. In the area ND where nothing is mounted, the thickness of the first resin 10 increases as the thickness measuring position moves from the top surface 2T of the electronic component 2 to the module substrate 3, so that the electronic component 2 is stably supported on the module substrate 3 by the first resin 10.

As the thickness of the first resin 10 on the area ND where nothing is mounted, the lengths (tt1, tt2, and tt3) in the direction perpendicular to the substrate surface 3P of the module substrate 3 may be used. In this case, the thickness of the first resin 10 on the area ND where nothing is mounted decreases as the surface of the first resin 10 goes away from the electronic component 2. Specifically, in the example shown in FIG. 4, the relationship among the thicknesses is tt1>tt2>tt3. In this case, the minimum thickness of the first resin 10 on the area ND where nothing is mounted is the thickness at the bottom position 10B of the U-shape of the first resin 10. Next, the method for manufacturing the electronic component built-in module according to the embodiment will be described. The description below is an example, and the electronic component built-in module 1 may be manufactured by other methods.

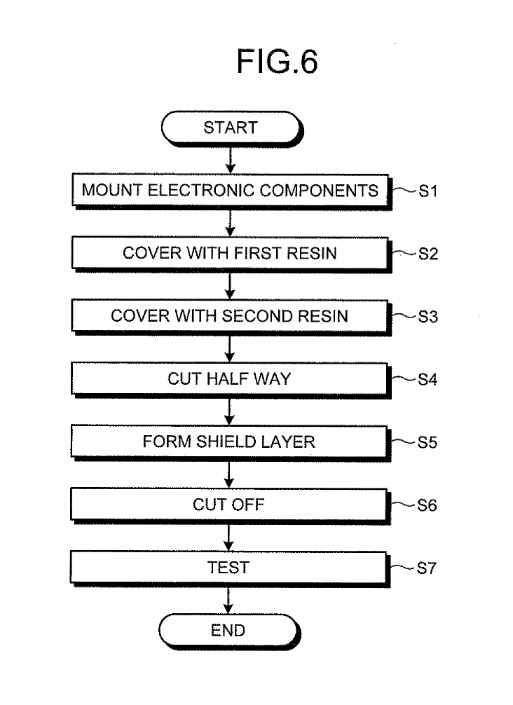

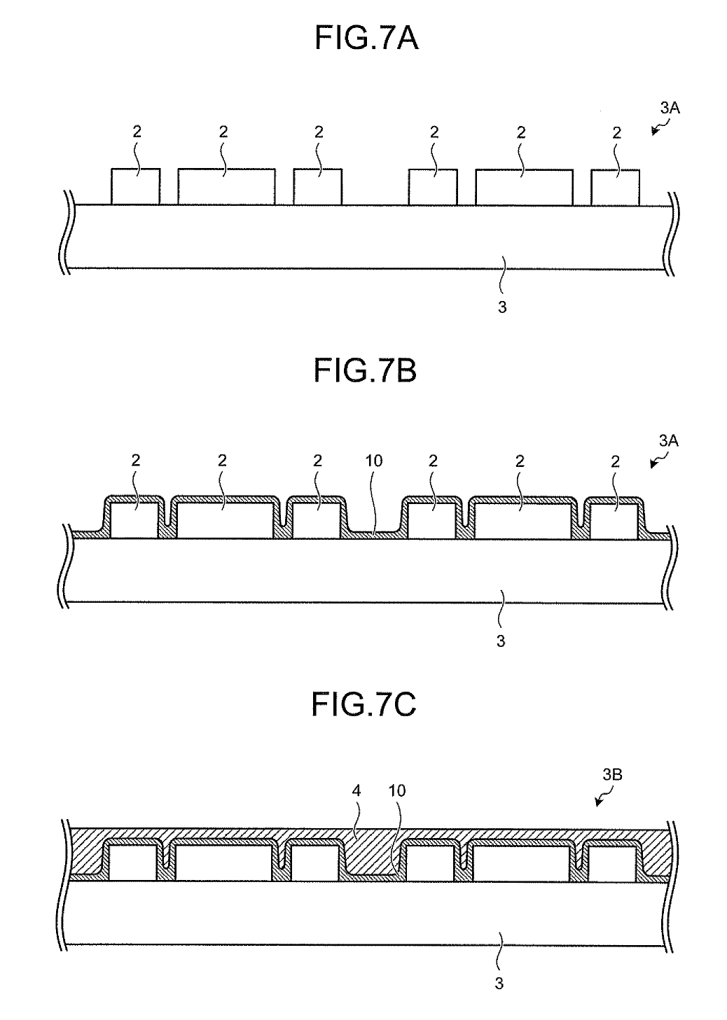

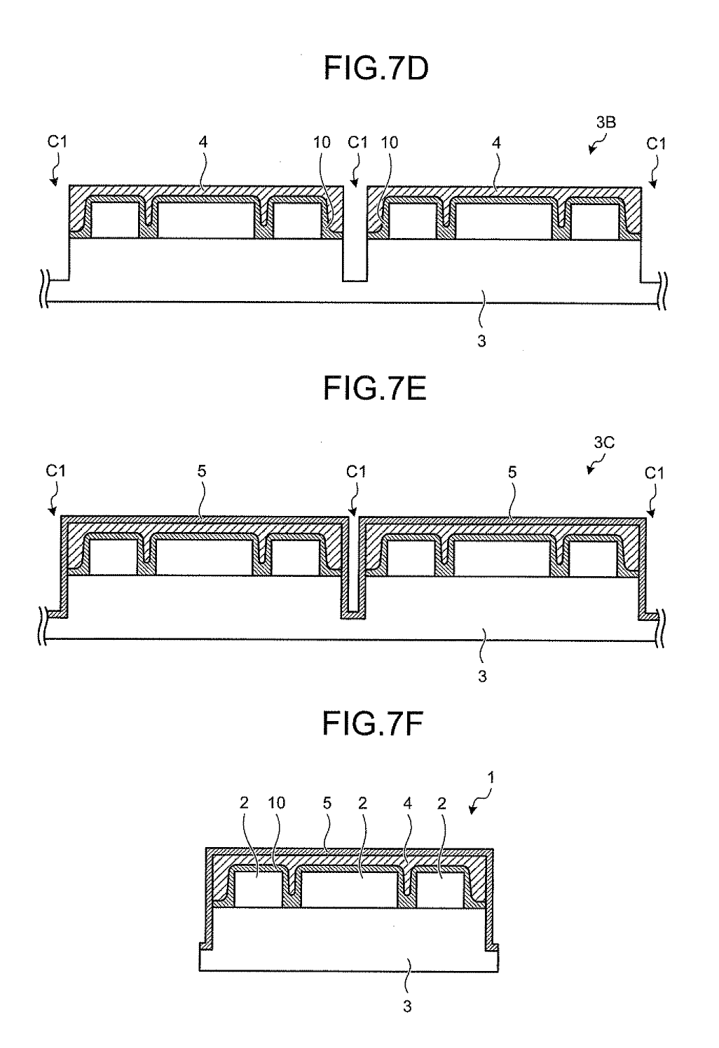

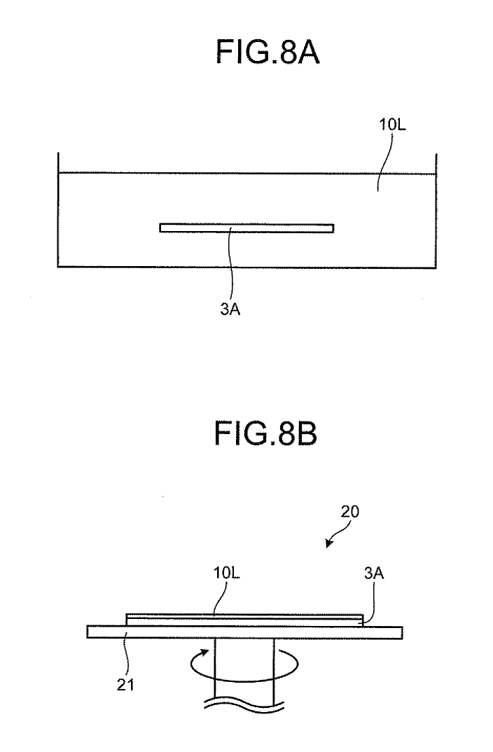

FIG. 6 is a flowchart showing the method for manufacturing the electronic component built-in module according to the embodiment. FIGS. 7A to 7F are illustrations of the method for manufacturing the electronic component built-in module according to the embodiment. FIGS. 8A and 8B are diagrams showing an example of a method for forming the first resin. When manufacturing the electronic component built-in module 1, in step S1, the electronic components 2 are mounted on the module substrate 3 shown in FIG. 7A (mounting process). This state is referred to as a module element body 3A.

For example, the module element body 3A is manufactured by the following procedure.

(1) Print a solder paste including the solder 6 on the terminal electrodes of the module substrate 3.
(2) Mount the electronic components 2 on the module substrate 3 by using a mounting apparatus (mounter).
(3) Bond the terminal electrodes of the electronic components 2 and the terminal electrodes of the module substrate 3 together by inserting the module substrate 3 on which the electronic components 2 are mounted into a reflow furnace and heating the solder paste so that the solder 6 in the solder paste is melted and thereafter hardened.
(4) Wash off fluxes attached to the surfaces of the electronic components 2 and the module substrate 3.

Next, when the module element body 3A is completed, the process proceeds to step S2, and, as shown in FIG. 7B, the electronic components 2 and the module substrate 3 of the module element body 3A are covered by the first resin 10. The first resin 10 that covers the electronic components 2 and the module substrate 3 is formed by adding fillers (for example, silica or alumina) to a thermo-setting resin (for example, epoxy resin, but not limited to this) and curing the thermo-setting resin. In this way, in the first resin 10, resin is disposed into gaps between the fillers and the pores 11 are formed. The first resin 10 covers the electronic components 2 and the module substrate 3 by coating a first resin solution created by adding fillers to a solution of a thermo-setting resin on the surface of the module element body 3A by a dip method or a spin coat method (coating process) and thermally curing the first resin solution.

The molecular weight of the thermo-setting resin that forms the first resin 10 is preferred to be 100 to 1000 before curing. If the molecular weight of the thermo-setting resin before curing is too high, viscosity of the thermo-setting resin before curing is too high, so that it is difficult to form the first resin 10 having an even film thickness. If the molecular weight is too low, viscosity of the thermo-setting resin before curing decreases, and the thermo-setting resin does not remain around the electronic components 2 but flows away. Therefore, the molecular weight of the thereto-setting resin that forms the first resin 10 is preferred to be within the range mentioned above.

The fillers included in the first resin 10 are preferred to have a near sphere shape. It is because, if such fillers are used, the size, shape, and distribution of the pores 11 included in the first resin 10 can be easily controlled. However, the shape of the fillers is not limited to this. The average diameter (D50) of the fillers included in the first resin is preferred to be greater than or equal to 1 μm and smaller than or equal to 10 μm, and more preferred to be greater than or equal to 2 μm and smaller than or equal to 7 μm. Regarding the particle size distribution of the fillers, D50/(D90-D10) is preferred to be set within a range of 0.1 to 0.8. By doing so, the fillers and the pores 11 in the first resin 10 can be easily distributed evenly. The average diameter (D50) is a diameter of the integrated value 50% (median diameter) when the diameters of a plurality of fillers are measured, D90 is a diameter when the integrated value is 90%, and D10 is a diameter when the integrated value is 10%. The particle size distribution of the fillers is defined from the number average value (median diameter) D50 measured by a particle size distribution meter, D10 corresponding to a cumulative frequency particle diameter of 10%, and D90 corresponding to a cumulative frequency particle diameter of 90%.

The type of the fillers is not particularly limited unless the fillers affect electrical characteristics of the electronic components 2 and circuits included in the electronic component built-in module 1. However, the fillers are preferred to have a good dispersibility in the thermo-setting resin included in the first resin 10. For example, when using fillers whose average diameter is smaller than 1 μm, the specific surface area increases. Therefore, the necessary amount of thermosetting resin increases and the porosity decreases, and thus the effect to prevent the solder 6 from moving or spreading decreases. When using fillers whose average diameter is greater than 10 μm, the film thickness of the first resin 10 coated on the surface of the module element body 3A needs to be large. Further, there are a risk that the strength of the formed first resin 10 decreases and cracks easily occur and a risk that the sizes of the pores 11 become large and the effect to prevent the solder from moving or spreading decreases.

Fillers having a large average diameter (D50) may be added to the fillers. The large average diameter (D50) of the fillers is preferred to be greater than or equal to 10 μm and smaller than or equal to 50 μm. The additive amount of the fillers having the large average diameter (D50) is preferred to be greater than or equal to 5 vol % and smaller than or equal to 30 vol % of the total amount of added fillers. In this way, by mixing fillers having different average diameters, it is possible to adjust a packing state among the fillers. It is easy to realize a desired pore diameter and pore distribution by an appropriate resin combination. When using fillers having different average diameters, the same type of fillers may be used, or different types (compositions) of fillers may be used. The types of the fillers are not particularly limited.

FIG. 8A shows an example in which a first resin solution 10L is coated on the surface of the module element body 3A by the dip method. This method includes a coating process in which the module element body 3A is dipped into the first resin solution 10L filled in a solution tank, and a film thickness reduction process in which at least the thickness of the first resin solution 10L coated on the top surfaces 2T of the electronic components 2 is reduced by pulling up the module element body 3A and removing redundant first resin solution 10L. When removing the redundant first resin solution 10L, vibration may be added to the module element body 3A by ultrasound or the like. In this way, it is possible to efficiently remove the redundant first resin solution 10L and reduce the film thickness of the first resin solution 10L.

FIG. 8B shows an example in which the first resin solution 10L is coated on the surface of the module element body 3A by the spin coat method. This method includes a coating process in which the first resin solution 10L is coated on the module element body 3A by using a table coater or a curtain coater, and a film thickness reduction process in which at least the thickness of the first resin solution 10L coated on the top surfaces 2T of the electronic components 2 is reduced by placing the module element body 3A on a rotation table 21 of a spin coater 20 and rotating the module element body 3A. In the film thickness reduction process, the rotation table 21 is rotated at a relatively low speed so that the film thickness of the first resin solution 10L coated on the module element body 3A becomes uniform.

Since the spin coat method is a method for reliably removing the redundant first resin solution 10L, structures shown in FIGS. 4 and 5 in which the thickness of the first resin 10 on the area ND where nothing is mounted is larger than the thickness of the first resin 10 on the surface RD of the electronic component opposite to the substrate are easily formed. The spin coat method is a method for easily forming the structures of the first resin 10 described above even when the surface of the module element body 3A has a concave-convex shape due to the electronic components 2. In other words, by using the spin coat method, it is possible to reliably remove the redundant first resin solution 10L and leave an appropriate amount of the first resin solution 10L on the top surfaces 2T of the electronic components 2 and in gaps between the adjacent electronic components 2. The method for coating the first resin solution 10L on the surface of the module element body 3A is not limited to those described above.

When the first resin solution 10L is coated on the surface of the module element body 3A, the first resin solution 10L is heated for a predetermined time period to cure the thermo-setting resin (first curing process). In this way, the first resin 10 is formed on the surface of the module element body 3A. Next, the process proceeds to step S3, and as shown in FIG. 70, the first resin 10 is covered by the second resin 4. The second resin 4 is formed of, for example, an epoxy resin. In the embodiment, a sheet-shaped material of an epoxy resin is placed on the surface of the first resin 10 (covering process), and the sheet-shaped material is heat-pressed in a vacuum chamber to cure the second resin 4 (second curing process). In this way, the surface of the first resin 10 is covered by the second resin 4. As a result, the electronic components 2 are sealed by the second resin 4 via the first resin 10. This state is referred to as a sealed body 3B.

Next, the process proceeds to step S4, and as shown in FIG. 7D, the module substrate 3 of the sealed body 3B is cut half way into units of the electronic component built-in modules 1 (units divided by Cl in FIG. 7D) (half dice). In this case, the second resin 4 and the first resin 10 are also cut into units of the electronic component built-in modules 1 at the same time. Next, the process proceeds to step S5, and as shown in FIG. 7E, the shield layer 5 is formed on the surface of the sealed body 3D after the half dice. This state is referred to as a module aggregate body 3C. The shield layer 5 is obtained by, for example, forming a first cupper layer by nonelectrolytic plating, then forming a second cupper layer by electrolytic plating, and further forming a Ni layer as a rust-proof layer by electrolytic plating. The shield layer 5 is formed on an as-needed basis.

When the shield layer 5 is formed, the process proceeds to step S6, and the module substrate 3 of the module aggregate body 3C is cut completely into units of the electronic component built-in modules 1 (units divided by Cl in FIG. 7E). In this way, the electronic component built-in module 1 shown in FIG. 7F is formed. The electronic component built-in module 1 is tested in step S7, and the electronic component built-in module 1 which has passed the test is completed as a product. The procedure described above is a procedure of the method for manufacturing the electronic component built-in module according to the embodiment, and the electronic component built-in module 1 including the first resin 10 can be manufactured by the procedure.

The first resin 10 of the electronic component built-in module 1 manufactured in this way is not exposed to the outside of the shield layer 5. If the first resin 10 including the pores 11 is exposed to the outside of the electronic component built-in module 1, there is a risk that water is introduced from the outside through the first resin 10. However, in the embodiment, the shield layer 5 is formed on the surface of the second resin 4, and the first resin 10 is covered by the shield layer 5, so that water is not introduced. As a result, water is highly prevented from entering into the electronic component built-in module 1, so that the risk that cracks or the like occur in the first resin 10 or the second resin 4 is extremely low. Based on this, the durability of the electronic component built-in module 1 improves.

Although a part of the first resin 10 appears on the surface of the second resin 4 by the half dice in step S4, the surface area is increased by the pores 11 of the first resin 10, so that the contact between the shield layer 5 and the first resin 10 is improved. As a result, when forming the shield layer 5, there is an advantage that the shape retaining effect of the shield layer 5 increases. When forming the shield layer 5, the first resin 10 may not be in contact with the shield layer 5. However, when manufacturing a plurality of electronic component built-in modules 1 from one substrate, it is difficult to make such a structure.

In the method for manufacturing the electronic component built-in module 1 according to the embodiment, although a part of the first resin 10 appears on the surface of the second resin 4 by the half dice, the first resin 10 appearing on the surface of the second resin 4 can be covered by forming the shield layer 5. As a result, water is not introduced into the completed electronic component built-in module 1, so that the durability of the electronic component built-in module 1 improves as described above.

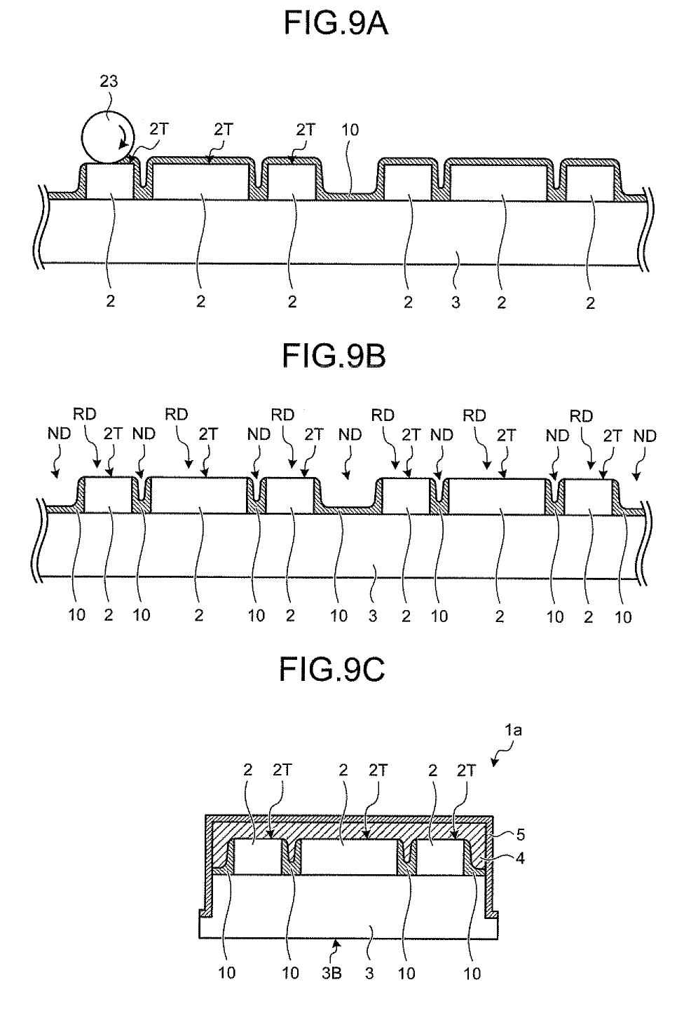

FIGS. 9A to 9C are illustrations showing a manufacturing method when the first resin is not formed on the surfaces of the electronic components in the method for manufacturing the electronic component built-in module according to the embodiment. As shown in FIG. 5, when the first resin 10 is not formed on the top surfaces 2T of the electronic components 2, the first resin solution 10L needs to be removed from the top surfaces 2T of the electronic components 2 (the film thickness needs to be 0) in the film thickness reduction process in step S2. For example, as shown in FIG. 9A, by rolling an absorbing roller 23 on the top surfaces 2T of the electronic components 2 on which the first resin solution 10L is coated, the first resin solution 10L is removed by the absorbing roller 23. The absorbing roller 23 is, for example, a roller having a porous material (urethane resin, or the like) on its outer circumference.

In this way, as shown in FIG. 9B, the first resin solution 10L is removed from the top surfaces 2T of the electronic components 2, and a state is created in which the first resin solution 10L is present on the surfaces RD of the electronic components opposite to the substrate (corresponding to the top surfaces 2T of the electronic components 2) and the first resin solution 10L is not present on the areas ND where nothing is mounted. Thereafter, by thermo-setting the first resin solution 10L and performing steps from S3 to S6 described above, it is possible to manufacture an electronic component built-in module 1a in which the first resin 10 is not formed on the top surfaces 2T of the electronic components 2 as shown in FIG. 9C.

As described above, in the embodiment, in the electronic component built-in module 1, the electronic components and the substrate are covered by the first resin including pores, further the first resin is covered by the second resin, and thereby the electronic components are sealed by the second resin via the first resin. When the electronic component built-in module is heated by the reflow in the secondary mounting operation, the solder inside the electronic component built-in module melts, and thereby a phenomenon may occur in which the solder is moved or spread by the melting and expansion of the solder or the melted solder is moved or spread by volume expansion of flux residues and absorbed moisture due to evaporation.

In the embodiment, pores for absorbing a volume change of the electronic component built-in module and absorbing gas generated in the electronic component built-in module are provided in the first resin that covers the electronic components. Based on this, even when the solder is melted by the reflow in the secondary mounting operation, a volume expansion that causes the solder to move or spread is absorbed by the pores included in the first resin. As a result, it is possible to prevent the solder movement or the solder spreading from occurring, which is caused when the solder in the electronic component built-in module is melted by the heat generated when the electronic component built-in module is mounted.

### Evaluation

The electronic component built-in module 1 (see FIG. 1) including the above-described first resin 10 has been manufactured and the movement of the solder and the strength of the first resin 10 have been evaluated. To form the first resin 10, a resin solution, in which various spherical fillers are mixed in a solution of epoxy resin and the solution is diluted by a solvent, has been prepared. The resin solution has been coated by the dip method on the module substrate 3 on which the electronic components 2 are mounted, the resin solution has been dried for two hours in a room temperature and has been thermally cured for an hour at 150° C., and thereby the electronic components 2 and the module substrate 3 have been covered by the first resin 10. A resin sheet that forms the second resin 4 has been pressure-bonded to the first resin 10 by a vacuum heat press and has been thermally cured for an hour at 150° C., and thereby the electronic components 2 and the module substrate 3 have been covered by the second resin 4 via the first resin 10. In this way, the electronic component built-in module to be evaluated (hereinafter referred to as evaluation body) has been manufactured.

A method for evaluating the movement of the solder will be described. The evaluation body has been heated in a reflow furnace and the movement of the solder in the evaluation body after the reflow has been observed by using transmission X-ray. The evaluation body in which the movement of the solder is observed has been determined to be an evaluation body with movement, and the evaluation body in which the movement of the solder is not observed has been determined to be an evaluation body without movement. A plurality of electronic component built-in modules 1 have been created for each condition such as a porosity and an average diameter, and a ratio of the number of evaluation bodies in which the movement of the solder is observed to the total number of evaluation bodies has been evaluated on a percentage (%) basis. The condition of the reflow is as follows:

As preprocessing for drying, the evaluation body has been left in an environment of 1.25° C. for 24 hours. As preprocessing for moisture absorption, the evaluation body after the drying has been left in an environment of 60° C. and relative humidity of 60% for 120 hours. Thereafter, the reflow has been performed under the condition described below. The evaluation body after the drying and the moisture absorption is inserted into the reflow furnace, then the temperature in the reflow furnace is raised to 150° C., and thereafter the temperature is raised to 180° C. in 120 seconds. The temperature in the reflow furnace is raised to 230° C. and then the reflow is started. During the reflow, the temperature in the reflow furnace is controlled so that the temperature is least 230° C. and the maximum temperature is 260° C.±3° C., and the temperature is held for 30 seconds. Thereafter, the evaluation body is taken out from the reflow furnace, and the reflow is completed.

### First Evaluation Example

Evaluation bodies respectively including first resins 10 having different porositys have been manufactured by using spherical fillers with an average diameter of 3 μm. The evaluation result is shown in table 1. The porosity has been changed as shown in table 1. The average diameter of the pores is 0.7 μm. The average diameter of the pores is a value of D50. In the first evaluation example, the movement of the solder and the strength of the first resin 10 have been evaluated. The strength of the first resin 10 has been evaluated on the basis of presence or absence of the cracks. The cracks in the first resin 10 have been observed by transmission X-ray. As known from table 1, when the porosity is smaller than 0.1%, the movement of the solder 6 cannot be sufficiently prevented. On the other hand, when the porosity is 40%, the strength of the first resin 10 is not sufficient. For this reason, the porosity is preferred to be greater than or equal to 0.1% and smaller than or equal to 30%.

TABLE 1

| | | | | | | | | | |
|---|---|---|---|---|---|---|---|---|---|
| Porosity | <0.1% | 0.1% | 1% | 5% | 7% | 10% | 20% | 30% | 40% |
| Movement | 73 | 0 | 0 | 0 | 0 | 0 | 0 | 0 | 0 |
| of solder [%] | | | | | | | | | |
| Cracks in | 0 | 0 | 0 | 0 | 0 | 0 | 0 | 0 | 54 |
| 1st resin [%] | | | | | | | | | |

### Second Evaluation Example

Evaluation bodies respectively including first resins 10 having different average diameters of the pores have been manufactured by changing a mixing ratio of one or at least two fillers among fillers respectively having average diameters of 1 μm, 3 μm, 5 μm, 7 μm, and 30 μm. The average diameter of the pores has been changed as shown in table 2. The average diameter of the pores is a value of D50. The evaluation result is shown in table 2. As known from table 2, when the average diameter of the pores is smaller than 0.1 μm, the movement of the solder 6 cannot be prevented. On the other hand, when the average diameter of the pores is 20 μm, the movement of the solder 6 cannot be sufficiently prevented. For this reason, the average diameter of the pores is preferred to be greater than or equal to 0.1 μm and smaller than or equal to 10 μm.

TABLE 2

| | | | | | | | |
|---|---|---|---|---|---|---|---|
| Average diameter | <0.1 μm | 0.1 μm | 1 μm | 5 μm | 7 μm | 10 μm | 20 μm |
| of pores | | | | | | | |
| Movement | 100 | 0 | 0 | 0 | 0 | 0 | 27 |
| of solder (%) | | | | | | | |

### Third Evaluation Example

Evaluation bodies respectively including first resins 10 having different average diameters of the fillers have been manufactured by changing a mixing ratio of one or at least two fillers among fillers respectively having average diameters of 1 μm, 3 μm, 5 μm, 7 μm, and 30 μm. The average diameter of the fillers has been changed as shown in table 3. The average diameter of the fillers is a value of D50. The evaluation result is shown in table 3. As known from table 3, when the average diameter (D50) of the fillers is smaller than 1 μm, the movement of the solder 6 cannot be sufficiently prevented. On the other hand, when the average diameter (D50) of the fillers is 15 μm, the strength of the first resin 10 is not sufficient. For this reason, the average diameter (D50) of the fillers is preferred to be greater than or equal to 1 μm and smaller than or equal to 10 μm.

TABLE 3

| | | | | | | |
|---|---|---|---|---|---|---|
| Average diameter | <1 μm | 1 μm | 5 μm | 7 μm | 10 μm | 15 μm |
| (D50) of fillers | | | | | | |
| Movement of | 45 | 0 | 0 | 0 | 0 | 0 |
| solder [%] | | | | | | |
| Cracks in | 0 | 0 | 0 | 0 | 0 | 64 |
| 1st resin [%] | | | | | | |

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An electronic component built-in module comprising:
an electronic component;
a substrate on which the electronic component is mounted;
a first resin that is formed of a resin including pores and covers the electronic component and the substrate and whose thickness on an area where the electronic component is not mounted on a surface of the substrate is larger than that on a surface of the electronic component opposite to a surface facing the substrate; and
a second resin that covers a surface of the first resin and has a porosity smaller than that of the first resin.

2. The electronic component built-in module according to claim 1, wherein the electronic component is mounted on the substrate with solder.

3. The electronic component built-in module according to claim 2, wherein the first resin covers a solder fillet mounting on the substrate the electronic component in the area where the electronic component is not mounted.

4. The electronic component built-in module according to claim 1, wherein the thickness of the first resin on a surface of the electronic component opposite to a surface attached to the substrate is 0.

5. The electronic component built-in module according to claim 1, wherein the thickness of the first resin from a side surface of the electronic component in the area where the electronic component is not mounted increases as the distance from the substrate decreases.

6. The electronic component built-in module according to claim 1, wherein the average diameter (D50) of the pores included in the first resin is greater than or equal to 0.1 μm and smaller than or equal to 10 μm.

7. The electronic component built-in module according to claim 1, wherein, as the distribution of the size of the pores, the porosity of the first resin is greater than or equal to 0.1% and smaller than or equal to 30%.

8. The electronic component built-in module according to claim 1, wherein the first resin includes fillers having an average diameter (D50) greater than or equal to 1 μm and smaller than or equal to 10 μm.

9. The electronic component built-in module according to claim 1, wherein the second resin is covered with a metal layer.

10. A method of manufacturing an electronic component built-in module, the method comprising:
mounting an electronic component on a substrate by solder;
coating a first resin solution into which fillers are mixed on the electronic component mounted on the substrate and the substrate;
reducing at least a thickness of the first resin solution coated on a surface of the electronic component opposite to a surface attached to the substrate;
curing the first resin;
covering the cured first resin with a second resin; and
curing the second resin.
